(19) United States
(12) Patent Application Publication
(10) Pub. No.: US 2014/0159543 A1
(43) Pub. Date: Jun. 12, 2014

(54) VIBRATOR AND PRODUCTION METHOD THEREOF, AND VIBRATION WAVE DRIVING DEVICE

(71) Applicant: CANON KABUSHIKI KAISHA, Tokyo (JP)

(72) Inventor: Yutaka Maruyama, Tokyo (JP)

(73) Assignee: CANON KABUSHIKI KAISHA, Tokyo (JP)

(21) Appl. No.: 14/080,113

(22) Filed: Nov. 14, 2013

(30) Foreign Application Priority Data
Dec. 6, 2012 (JP) 2012-267650

(51) Int. Cl. H01L 41/09; H01L 41/25

(52) U.S. Cl. CPC H01L 41/09; H01L 41/25
USPC 310/311; 29/25.35

(57) ABSTRACT

Provided is a vibrator including a substrate; a piezoelectric element including a piezoelectric layer and an electrode layer, the piezoelectric element being fixed to the substrate; and a ceramics layer disposed between the substrate and the piezoelectric element, the ceramics layer having a thickness of more than 0.5 times and less than 1 time a thickness of the piezoelectric layer.

### BACKGROUND OF THE INVENTION

1. Field of the Invention

The present invention relates to a vibrator, a production method therefor, and a vibration wave driving device, and more particularly, to a vibrator including a piezoelectric element fixed onto a substrate, a production method therefor, and a vibration wave driving device using the vibrator.

2. Description of the Related Art

Hitherto, in a vibration wave driving device (vibration wave actuator), a piezoelectric element is generally used as a vibration source for a vibrator. As the piezoelectric element, a single plate-shaped piezoelectric element, and in recent years, a laminated piezoelectric element including a large number of laminated piezoelectric layers are used (see Japanese Patent Application Laid-Open No. 2004-304887).

FIG. 8 is an external perspective view of a linear type vibration wave (ultrasonic wave) driving device 20 as described in Japanese Patent Application Laid-Open No. 2004-304887. The linear type vibration wave driving device includes a vibrator 21 and a linear slider 26 as a driver held in press contact with the vibrator 21.

The vibrator 21 includes a laminated piezoelectric element 23 and a vibrating plate 22. The laminated piezoelectric element 23 includes piezoelectric layers and electrode layers alternately laminated on each other. The vibrating plate 22 is made of a metal, and is bonded to the laminated piezoelectric element 23 with an adhesive made of a resin.

The vibrating plate 22 made of a metal includes a rectangular-shaped plate portion and two protrusion portions 24 formed to protrude from an upper surface of the plate portion. In end surfaces of the protrusion portions 24, contact portions 25 are formed. The contact (friction) portions 25 are members to be brought into direct contact with the linear slider 26 serving as a driven member, and hence have abrasion resistance.

The vibrator 21 of the linear vibration wave driving device 20 is formed in such a manner that resonant frequencies of two bending vibration modes (a secondary bending vibration mode in a long axis direction and a primary bending vibration mode in a short axis direction) are substantially matched with each other. Then, by inputting predetermined high-frequency voltages differing in phase by about π/2, the vibrator 21 is excited to cause circular motion or elliptic motion in the protrusion portions 24. The circular motion or the elliptic motion generates relative movement force in the linear slider 26, which is in contact with the vibrator 21 in a pressurized state, through friction force between the vibrator 21 and the linear slider 26. The relative movement force enables the linear slider 26 to reciprocate linearly as indicated by arrows.

For producing the laminated piezoelectric element 23, a green sheet serving as the piezoelectric layer is first produced from piezoelectric material powder and an organic binder by a doctor blade method and the like. In a predetermined position on the green sheet, an electrode material paste is printed to obtain the electrode layer.

Then, a predetermined number of the green sheets are placed on each other to have a plane-shape as a whole, and are pressed to be laminated. After that, the piezoelectric layers and the electrode layers are simultaneously baked to be integrated to each other and are then subjected to polarization treatment. Finally, the integrated piezoelectric layers and electrode layers are subjected to mechanical working to be finished to have a predetermined dimension.

Further, Japanese Patent No. 2,842,448 proposes the following piezoelectric/electrostrictive film-type actuator. Specifically, the electrode materials and the piezoelectric materials are stacked one by one in a layered manner on at least one surface of a substrate and are subjected to a heating process. In this manner, the piezoelectric/electrostrictive film-type actuator has an integrated layered structure.

Further, Japanese Patent Application Laid-Open No. 2011-254569 proposes a vibrator including a piezoelectric element having a piezoelectric layer and an electrode layer fixed to a substrate. The substrate is vibrated with vibration energy of the piezoelectric element to output vibration energy of the vibrator. The piezoelectric element is fixed to the substrate through intermediation of a joining layer made of a ceramics layer containing glass powder provided between the piezoelectric element and the substrate.

In the above-mentioned vibrator 21 of the vibration wave driving device of the conventional example illustrated in FIG. 8, the laminated piezoelectric element and the vibrating plate (hereinafter referred to as “substrate”) 22 made of a metal are bonded to each other with an adhesive made of a resin. However, the adhesive made of a resin is soft compared to the piezoelectric element and the metal, and hence the vibration damping of the vibrator becomes large. In particular, when the temperature of the resin increases, the vibration wave driving device results in a decrease in efficiency.

Further, when the vibration wave driving device is miniaturized, the variation in thickness of an adhesive layer and the position accuracy based on the adhesion have greater effects on the performance of the miniaturized vibration wave driving device, with the result that the variation in performance of the miniaturized vibration wave driving device increases.

Further, in a conventional method of producing a laminated piezoelectric element, the facility investment amount for production devices such as a molding machine for molding a green sheet from piezoelectric material powder, a lamination press, and a mechanical processing machine is great, which is a factor for increasing production cost.

In this regard, as in the above-mentioned conventional example as described in Japanese Patent No. 2,842,448, it is supposed that, at the same time when the laminated piezoelectric element is produced, without providing the adhesive layer, the laminated piezoelectric element is directly fixed (joined) on the substrate. However, the joining strength between the ceramics substrate and the electrode layer made of a noble metal is weak due to the low chemical reactivity therebetween. Therefore, the piezoelectric element is likely to peel off from the ceramics substrate during baking and sometimes peels off from the ceramics substrate due to the vibration of the actuator.

Then, the above-mentioned conventional example as described in Japanese Patent Application Laid-Open No. 2011-254569 proposes a vibrator obtained by simultaneously baking the piezoelectric element and the ceramics substrate through intermediation of the joining layer containing glass powder provided between the piezoelectric element and the ceramics substrate, and melting the glass powder to join the piezoelectric element to the ceramics substrate. However, there still remains a demand for the enhancement of performance of the vibrator.

### SUMMARY OF THE INVENTION

One embodiment of the present invention relates to a vibrator capable of outputting vibration energy with a small loss and good efficiency by suppressing damping of vibration involved in miniaturization with a low-cost configuration, a production method for the vibrator, or a vibration wave driving device using the vibrator.

One embodiment of the present invention relates to a vibrator including a substrate; a piezoelectric element including a piezoelectric layer and an electrode layer; and a ceramics layer disposed between the substrate and the piezoelectric element, the ceramics layer having a thickness of more than 0.5 times and less than 1 time a thickness of the piezoelectric layer.

Further, another embodiment of the present invention relates to a vibration wave driving device, including as a driving power source the above-mentioned vibrator.

Further, another embodiment of the present invention relates to a method of producing a vibrator, including: forming a ceramics layer containing glass powder on a substrate; forming a piezoelectric element including a piezoelectric layer and an electrode layer on the ceramics layer; and integrating the substrate, the ceramics layer, and the piezoelectric element by baking the substrate, the ceramics layer, and the piezoelectric element together, in which as the glass powder glass powder containing silicon oxide, boron oxide, and at least one kind of alkali earth metal oxide is used, and the ceramics layer contains the glass powder in an amount of 0.5% by weight or more and 10% by weight or less with respect to a weight of ceramics powder of the ceramics layer and is formed on the substrate to a thickness of more than 0.5 times and less than 1 time a thickness of the piezoelectric layer.

Further features of the present invention will become apparent from the following description of exemplary embodiments with reference to the attached drawings.

### BRIEF DESCRIPTION OF THE DRAWINGS

FIGS. 1A, 1B and 1C are respectively front, side, and plan views, each illustrating an exemplary configuration of a vibrator according to Example 1 of the present invention.

FIG. 2 is a view illustrating performance evaluation of the vibrator according to Example 1 of the present invention and illustrating a support method at a time of applying a voltage to the vibrator.

FIG. 3 is a graph showing a relationship between the applied voltage and the vibration velocity, which is a result of performance evaluation of the vibrator according to Example 1 of the present invention.

FIG. 4 is a graph showing a relationship between the applied voltage and the vibration velocity, which is a result of performance evaluation of the vibrator according to Example 1 of the present invention.

FIGS. 5A, 5B and 5C are respectively front, side, and plan views, each illustrating an exemplary configuration of a vibrator according to Example 2 of the present invention.

FIGS. 6A, 6B and 6C are respectively front, side, and plan views, each illustrating an exemplary configuration of a vibrator according to Example 3 of the present invention.

FIG. 7 is a view illustrating a linear vibration wave driving device incorporating the vibrator according to Examples 2 and 3 of the present invention.

FIG. 8 is a view illustrating a linear vibration wave driving device according to a conventional example.

### DESCRIPTION OF THE EMBODIMENTS

An embodiment for carrying out the present invention is described by way of the following examples.

### Examples

### Example 1

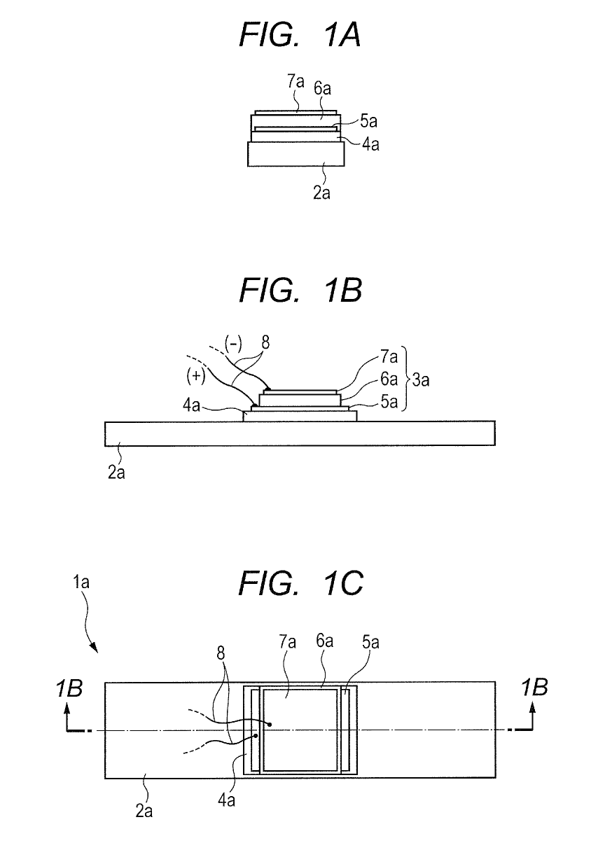

As Example 1, an exemplary configuration of a vibrator to which the present invention is applied is described with reference to FIGS. 1A to 1C. FIGS. 1A, 1B, and 1C are a front view, a side view, and a plan view, respectively.

Specifically, as illustrated in FIGS. 1A to 1C, a vibrator 1a according to this example is configured as a vibrator for causing longitudinal vibration assuming that the vibrator 1a is applied to a vibration wave driving device. FIG. 1B illustrates a cross-section taken along alternate long and short dashed lines 1B-1B illustrated in FIG. 1C.

The vibrator 1a according to this example is configured in such a manner that a piezoelectric element 3a including a piezoelectric layer and an electrode layer is joined to a substrate 2a, and the substrate 2a is also vibrated with vibration energy of the piezoelectric element 3a to output vibration energy of the vibrator 1a.

The vibrator 1a includes the plate-shaped substrate 2a and the piezoelectric element 3a, and a ceramics layer 4a containing a glass component produced by melting of glass powder during baking is provided between the substrate 2a and the piezoelectric element 3a. In the piezoelectric element 3a, an electrode layer 5a, a piezoelectric layer 6a, and an electrode layer 7a are successively laminated, and the electrode layers 5a and 7a are opposed to each other with the piezoelectric layer 6a interposed therebetween.

As described later, in the vibrator 1a, the ceramics layer 4a on the substrate 2a is baked simultaneously together with the electrode layer 5a, the piezoelectric layer 6a, and the electrode layer 7a, with the result that the piezoelectric element 3a is baked and is joined to be integrated with the substrate 2a via the ceramics layer 4a serving as a joining layer.

That is to say, the piezoelectric element 3a serving as a source for generating vibration energy and the substrate 2a serving as a vibrating plate which is vibrated with the vibration energy generated by the piezoelectric element 3a are joined to each other via the ceramics layer 4a for joining and integrated as the vibrator 1a.

Further, the electrical conduction with an external power source is made by joining two conductive wires 8 onto the electrode layers 5a, 7a through use of conductive paste, solder, or the like.

The electrode layers 5a, 7a are supplied with a high-frequency voltage from an external power source for controlling vibration of the piezoelectric element 3a. The piezoelectric layer 6a expands or contracts (is strained) due to the high-frequency voltage, and the expansion and contraction are propagated together with the substrate 2a and output outside from the vibrator 1a as vibration energy. The vibrator 1a in which the piezoelectric element 3a is integrated with the substrate 2a via the ceramics layer 4a is subjected to polarization treatment (described later), and hence the vibrator 1a can generate vibration in a longitudinal direction by applying a voltage at a predetermined frequency to the electrode layers 5a, 7a.

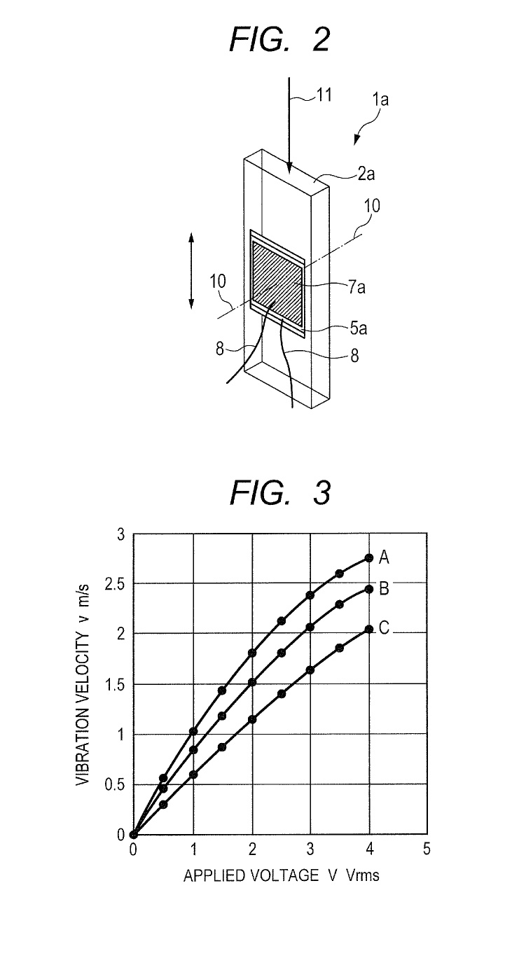

FIG. 2 illustrates a method of measuring vibration velocity of the vibration in a longitudinal direction of the vibrator 1a with laser light 11 of a laser Doppler velocimeter. As illustrated in FIG. 2, a center portion of the vibrator 1a is held by being sandwiched by two contact pins 10.

Then, when a predetermined high-frequency voltage V is applied through the conducting conductive wires 8 conducted to the electrode layers 5a, 7a, and the frequency of the high-frequency voltage V is swept from a frequency larger than the resonant frequency (about 190 KHz) of the vibration in a longitudinal direction to a frequency smaller than the resonant frequency, the maximum vibration velocity v (during resonance) of the longitudinal vibration of the vibrator 1a in directions indicated by the arrows is measured to evaluate the vibration performance of the vibrator 1a.

The piezoelectric element 3a is disposed at the center of the substrate 2a. The substrate 2a has a length of 25 mm, a width of 9 mm, and a thickness of 0.25 mm.

The thickness of the electrode layers 5a, 7a is about 5 μm. The ceramics layer 4a is 11 mm in length and 8.5 mm in breadth; the electrode layer 5a is 10 mm in length and 8 mm in breadth; the piezoelectric layer 6a is 9 mm in length and 8.5 mm in breadth; and the electrode layer 7a is 8 mm in length and breadth.

FIG. 3 is a graph showing a relationship between the applied voltage V (effective voltage Vrms) and the maximum vibration velocity v (m/s) when the thickness of the piezoelectric layer 6a is set to 10 μm and the thickness of the ceramics layer 4a is set to 5 μm, 10 μm, and 15 μm. In FIG. 3, A, B, and C represent the cases where the thickness of the ceramics layer 4a is 5 μm, 10 μm, and 15 μm, respectively. The vibration velocity v becomes large when the voltage V is increased to 4 V, and the vibration velocity v reaches 2 m/s or more.

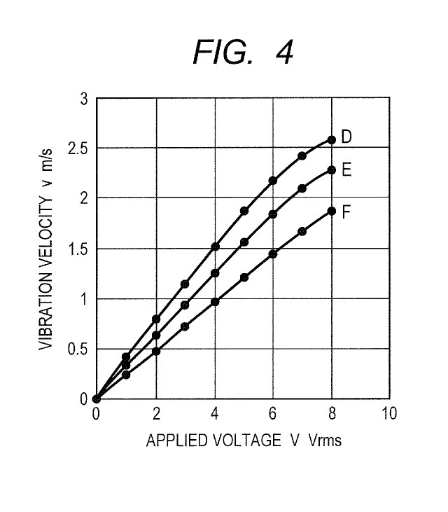

FIG. 4 is a graph showing a relationship between the applied voltage V (effective voltage Vrms) and the maximum vibration velocity v (m/s) when the thickness of the piezoelectric layer 6a is set to 20 μm, and the thickness of the ceramics layer 4a is set to 10 μm, 20 μm, and 30 μm. In FIG. 4, D, E, and F represent the cases where the thickness of the ceramics layer 4a is 10 μm, 20 μm, and 30 μm, respectively. In this case, unless the voltage V larger than that of FIG. 3 is applied, the vibration velocity v does not become large. When the voltage V is increased to 8 V, the vibration velocity v reaches almost 2 m/s or more.

In FIGS. 3 and 4, as the thicknesses of the piezoelectric layer 6a and the ceramics layer 4a increase, an increase in the vibration velocity v with respect to the voltage V decreases. The reason for this is that the thicknesses of the piezoelectric layer 6a and the ceramics layer 4a are loads, and the vibration damping (loss of vibration energy) increases even at the same applied voltage. Although not shown, even when the voltage V is increased to 4 V or more in FIG. 3 and the voltage V is increased to 8 V or more in FIG. 4, the vibration velocity v does not increase to 3 m/s or more although it increases slightly.

The reason for this is that, even when input energy is increased by increasing the voltage V, the input energy merely converts to heat generation (increase in temperature) of the vibrator 1a.

Further, according to durability test results obtained by driving the vibrator 1a for a long period of time (24 hours), no fatigue fracture (generation of cracks) under a stress generated by the vibration occurred and performance was not degraded in A to F of FIGS. 3 and 4 under the condition of a vibration velocity of 1.8 m/s.

However, it was found that peeling is likely to occur between the ceramics layer 4a and the electrode layer 5a during baking when the thickness of the ceramics layer 4a is 5 μm or less under the condition that the thickness of the piezoelectric layer 6a is 10 μm, and when the thickness of the ceramics layer 4a is 10 μm or less under the condition that the thickness of the piezoelectric layer 6a is 20 μm. The reason for this is as follows.

Although the electrode layer 5a, the piezoelectric layer 6a, and the electrode layer 7a are baked simultaneously together during baking and thus the piezoelectric element 3a contracts, the substrate 2a does not contract because the substrate 2a is made of baked ceramics. As a result, an internal stress is generated in the ceramics layer 4a strongly joined to the substrate 2a. Therefore, when the thickness of the ceramics layer 4a is too small, the ceramics layer 4a cannot withstand a generated internal stress, and peeling is likely to occur between the electrode layer 5a having weak joining force and the ceramics layer 4a.

On the other hand, it was also found that peeling does not occur between the substrate 2a and the ceramics layer 4a because the joining force therebetween is strong owing to the effect of melted glass.

Further, it is not preferred to excessively increase the thicknesses of the piezoelectric layer 6a and the ceramics layer 4a because a vibration loss thereof increases to result in increased applied voltage.

On the other hand, when the piezoelectric layer 6a is thin, the withstand voltage (dielectric strength) of the piezoelectric layer 6a decreases due to defects (voids, etc.) in the piezoelectric layer 6a. When the thickness of the piezoelectric layer 6a is less than 5 μm, an electric short-circuit is likely to occur during polarization treatment described later. Therefore, it is preferred that the thickness of the piezoelectric layer 6a be 5 μm or more.

It is preferred that the thickness of the piezoelectric layer 6a of the vibrator 1a be determined considering applicable voltage, actual loss of the vibrator 1a, and other factors.

On the other hand, as the thickness of the piezoelectric layer 6a is larger, the withstand voltage (dielectric strength) with respect to a thickness per unit (for example, per μm) generally increases. Therefore, a higher voltage can also be applied.

Further, in thick film printing by screen printing, a thickness in a range of 2 to 3 μm or more to 30 μm or less is generally acceptable.

From the foregoing, the thickness of the piezoelectric layer 6a is preferably about 5 μm to 25 μm, more preferably about 10 μm to 20 μm. Then, it can be considered to be preferred from FIGS. 3 and 4 that the thickness of the ceramics layer 4a be larger than 0.5 times and less than 1 time the thickness of the piezoelectric layer 6a, because the applied voltage is relatively low, and the vibration velocity increases.

Next, a production method for the vibrator 1a is described.

First, a plate-shaped baked ceramics is finished to have a predetermined dimension by grinding or cutting to obtain the substrate 2a in FIGS. 1A to 1C.

Next, ceramics powder paste capable of forming a thick film is prepared by mixing ceramics powder, glass powder described later, and an organic vehicle formed of an organic solvent and an organic binder. The ceramics powder paste is applied by printing onto one surface of the substrate 2a by screen printing.

Then, the applied ceramics powder paste mixed with the glass powder is heated at about 150° C. for about 10 minutes, and thus the organic solvent is removed and the applied ceramics powder paste is dried, to thereby form the ceramics layer 4a.

After that, an electrode layer is formed on the ceramics layer 4a as follows.

That is to say, conductive material powder paste prepared by mixing conductive material powder mixed with piezoelectric powder in advance, and an organic vehicle formed of an organic solvent and an organic binder is applied onto the ceramics layer 4a by screen printing. The conductive material powder paste is dried by heating at about 150° C. for about 10 minutes to form the electrode layer 5a on the ceramics layer 4a. Further, piezoelectric material powder paste capable of forming a thick film is prepared by mixing piezoelectric material powder and an organic vehicle formed of an organic solvent and an organic binder and is applied onto the surface of the electrode layer 5a by screen printing.

Then, the applied piezoelectric material powder paste is heated at about 150° C. for about 10 minutes, and thus the organic solvent is removed and the applied piezoelectric material powder paste is dried, to thereby form the piezoelectric layer 6a. After that, similarly to the electrode layer 5a, conductive material powder paste is applied on the piezoelectric layer 6a by screen printing and dried, to thereby form the electrode layer 7a.

As described above, application and drying are subsequently repeated, to thereby form on the substrate 2a the piezoelectric layer 4a, the electrode layer 5a, the piezoelectric layer 6a, and the electrode layer 7a.

The ceramics layer 4a on the substrate 2a thus formed, and the piezoelectric element 3a including the laminated electrode layer 5a, piezoelectric layer 6a, and electrode layer 7a are still in an unbaked state. Then, the resultant was heated from room temperature to 500° C. through use of an electric furnace to remove the organic binder, and then baked at 900° C. to 950° C. in an atmosphere of lead.

That is to say, the substrate 2a, the ceramics layer 4a, and the laminated electrode layer 5a, piezoelectric layer 6a, and electrode layer 7a were baked simultaneously, with the result that a piezoelectric element was produced by baking, and simultaneously, the piezoelectric element 3a was joined to (integrated with) the ceramics layer 4a and the substrate 2a.

After that, the conductive wires 8 were fixed to the electrode layers 5a, 7a through use of conductive paste, solder, or the like so as to make conduction, and a voltage was applied between the electrode layers 5a, 7a through the conductive wires 8 to subject the piezoelectric layer 6a to polarization treatment. The polarization treatment was performed under the following condition: a predetermined DC voltage (about 1 V/μm per thickness of the piezoelectric layer 6a) was applied between the electrode layers 5a, 7a for about 30 minutes on a hot plate heated to a high temperature of 170° C. to 200° C., with the electrode layer 5a being a ground (G) and the electrode layer 7a being a plus (+). In this case, the piezoelectric layer 6a is a layer which is subjected to polarization treatment and generates a displacement as a piezoelectric active part, and the piezoelectric characteristics of the piezoelectric layer 6a are directly related to the vibration characteristics of a vibrating plate and to the performance of a vibration wave driving device.

As a material for the substrate 2a, alumina (aluminum oxide), which is baked ceramics that is easily available and low-cost, is preferred because alumina is a material which does not damp in vibration (material having a smaller energy loss as a vibrator) compared to a metal.

When the purity of alumina is low, the mechanical strength thereof is degraded, and vibration damping as a vibrator increases. Therefore, high-purity alumina having a purity of 99.5% by weight or more and 99.99% by weight or less is more preferred. Further, alumina is hard and excellent in abrasion resistance, and hence is also preferred as a contact (friction) portion of a vibrator of a vibration wave driving device.

Note that, it is appropriate that the substrate 2a is made of a material which is stably bonded to the ceramics layer 4a in which glass powder is mixed in advance.

Besides alumina, general ceramics such as zirconia, silicon carbide, aluminum nitride, or silicon nitride may be used for the substrate 2a. This is because glass powder is mixed in the ceramics layer 4a in advance, and hence a glass component melted by baking enhances the adhesion strength with respect to the substrate 2a and the electrode layer 5a to enable joining.

As a piezoelectric material for forming the piezoelectric layer 6a, piezoelectric material powder which can be baked at a low temperature was used. The piezoelectric material powder can be baked at a low temperature by adding copper oxide to three-component system or multi-component system piezoelectric material powder in which lead zirconate and lead titanate (PbZrO₃—PbTiO₃) having a perovskite crystal structure containing lead are contained as a main component, and a small amount of a compound composed of multiple metal elements is added thereto to form solid solution.

The baking temperature at which satisfactory piezoelectric characteristics are obtained is 900° C. to 950° C. The baking temperature was able to be decreased by about 200° C. from that for conventional piezoelectric material powder.

As conductive material powder paste for forming the electrode layers 5a, 7a, a conductive material containing silver, silver and palladium, or palladium as a main component was used in which 15% by weight of piezoelectric material powder was added in advance.

The conductive material powder paste is basically a metal, and hence, the conductive material powder paste is easily baked and contracts quickly and greatly. Therefore, by mixing the piezoelectric material powder in the electrode layer 5a, the contraction of the electrode layer 5a caused by baking of the conductive material powder is suppressed, and thus the electrode layer 5a does not peel off from the ceramics layer 4a or the piezoelectric layer 6a easily.

Further, at the same time, the reaction between the mixed piezoelectric material powder and the ceramics layer 4a can also be expected. Note that, the similar effects are obtained even when the piezoelectric material powder to be added is the same component as that for the piezoelectric layer 6a or contains lead zirconate and lead titanate (PbZrO₃—PbTiO₃) as a main component. The mixed ratio between silver and palladium depends on the baking temperature, and the mixed proportion of palladium is adjusted in a range of 0% to 100% depending on the baking temperature of the piezoelectric material. When the baking temperature is 900° C. to 950° C., the mixed proportion of silver is preferably 100% by weight, or the respective mixed proportions of silver and palladium are preferably 95% to 98% by weight and 2% to 5% by weight in order to prevent electrical migration.

In this example, ceramics powder paste for forming the ceramics layer 4a is prepared by adding glass powder to the same piezoelectric material powder (serving as ceramics powder) as that for the piezoelectric layer 6a.

As the glass powder, glass powder (also referred to as glass frit) was used, which was obtained by mixing silicon oxide and boron oxide (boron trioxide), and further mixing bismuth oxide, alumina, an alkali metal oxide, or an alkali earth metal oxide; melting the mixture temporarily; and finely crushing the melted glass to an average particle diameter of 1 μm to 2 μm.

The obtained glass powder was added to the piezoelectric material powder in an amount of about 0.2% by weight to 10% by weight with respect to the weight of the piezoelectric material powder to obtain paste. By changing the blending ratio between silicon oxide and boron oxide, the softening point of glass can be varied depending on the baking temperature of the piezoelectric ceramics. Further, by selecting elements to be added, the reaction with the substrate 2a can also be increased.

The glass powder contained in the ceramics layer 4a is melted, softened, and fluidized during baking.

Then, it is supposed that the glass component of the melted glass powder gathers relatively in a great amount at the interfaces with respect to the substrate 2a and the electrode layer 5a and is likely to form chemical bonding to the substrate 2a and the electrode layer 5a. Note that, the reaction of the substrate 2a made of ceramics with the glass is stronger than that of the electrode layer 5a made of a noble metal, and the joining force of the substrate 2a with respect to the glass is also larger than that of the electrode layer 5a.

Further, although the piezoelectric layer 6a serving as a piezoelectric active layer expands or contracts to generate vibration during vibration of the vibrator 1a, the ceramics layer 4a serves as a buffer material for the substrate 2a to prevent the breakage of the piezoelectric element 3a. When the weight of the glass powder is less than 0.5% by weight with respect to the weight of the ceramics powder, the effect of joining with the substrate 2a is insufficient.

Note that, when the weight of the glass powder is more than 10% by weight with respect to the weight of the ceramics powder, the melted glass component diffuses to the substrate 2a greatly which is a drawback of the glass powder, which degrades the mechanical characteristics of the substrate 2a and also degrades the mechanical properties of the ceramics layer 4a.

From the foregoing, the weight of the glass powder was set to 0.5% by weight or more and 10% by weight or less with respect to the weight of the ceramics powder for the ceramics layer 4a.

Further, as the ceramics powder for the ceramics layer 4a, any ceramics can be used as long as the ceramics are baked at the baking temperature of the piezoelectric element 3a and has effective mechanical strength with respect to the binding between the substrate 2a and the piezoelectric element 3a. For example, the ceramics powder (alumina powder in this example) which is the same material as that for the substrate 2a is also preferred because the ceramics powder has good compatibility with the substrate 2a. For example, for a piezoelectric element formed of a lead-free piezoelectric material, such as a barium titanate-based piezoelectric material or a bismuth sodium titanate-based piezoelectric material, similarly having a piezoelectric property, other than the above-mentioned piezoelectric material powder made of lead zirconate and lead titanate, it is also effective to use the same kind of barium titanate-based powder or bismuth sodium titanate-based powder as a ceramics layer.

The glass powder has the following advantages: it is easy and possible to adjust the chemical composition of the glass powder so as to have suitable baking temperature and mechanical strength, and the glass powder can be applied to various materials for a substrate and ceramics.

### Example 2

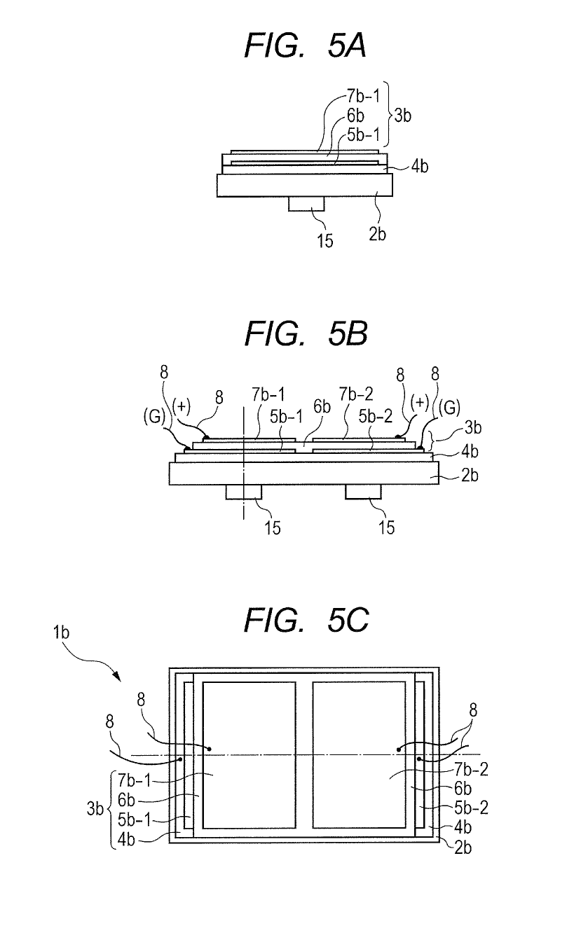

As Example 2, an exemplary configuration of a vibrator in a different form from Example 1 is described with reference to FIGS. 5A to 5C. FIGS. 5A, 5B, and 5C are a front view, a side view, and a plan view, respectively.

A vibrator 1b illustrated in FIGS. 5A to 5C is assumed to be applied to a linear vibration wave driving device shown in the conventional example. Note that, the production method, and the substrate, piezoelectric layer, electrode layer, and ceramics layer used in this example are basically the same as those of Example 1.

The vibrator 1b includes a plate-shaped substrate 2b and a piezoelectric element 3b, and a ceramics layer 4b made of ceramics containing glass powder is provided between the substrate 2b and the piezoelectric element 3b. The substrate 2b and the piezoelectric element 3b are fixed to and integrated with each other via the ceramics layer 4b by simultaneous baking as described later.

That is to say, the piezoelectric element 3b serving as a vibration energy generation source is fixed to and integrated with the substrate 2b which is vibrated with the vibration energy of the piezoelectric element 3b via the ceramics layer 4b, and in the piezoelectric element 3b serving as the vibrator 1b, electrode layers 5b-1, 5b-2, a piezoelectric layer 6b, and electrode layers 7b-1, 7b-2 are successively laminated.

An electrode layer 5b is divided into two electrode layers 5b-1 and 5b-2 which are insulated from each other. Similarly, an electrode layer 7b is also divided into two electrode layers 7b-1 and 7b-2 which are insulated from each other. The two divided electrode layers 5b-1, 5b-2 and the two divided electrode layers 7b-1, 7b-2 are respectively opposed to each other with the piezoelectric layer 6b interposed therebetween.

Further, the electrical conduction with an external power source and polarization treatment are carried out by fixing a conductive wire 8 onto each surface of the two divided electrode layers 5b-1, 5b-2 and the two divided electrode layers 7b-1, 7b-2 through use of conductive paste, solder, or the like.

After that, basically in the same way as in Example 1, a voltage was applied through the conductive wires 8, with the electrode layers 5b-1, 7b-1 respectively being a ground (G) and a plus (+) and the electrode layers 5b-2, 7b-2 respectively being a ground (G) and a plus (+). Thus, regions of the piezoelectric layer 6b where the electrode layers 5b-1, 7b-1 and the electrode layers 5b-2, 7b-2 were opposed were polarized. The polarization treatment was performed under the following condition: a predetermined DC voltage (about 1 V/μm per thickness of the piezoelectric layer 6b) was applied between the ground (G) and the plus (+) for about 30 minutes on a hot plate heated to a high temperature of 170° C. to 200° C.

In this case, the regions subjected to the polarization treatment are layers serving as piezoelectric active parts for generating a displacement, and the piezoelectric characteristics of the layers are directly related to the vibration characteristics of a vibrating plate and to the performance of a vibration wave driving device.

The substrate 2b has a length of 9 mm, a width of mm, and a thickness of 0.25 mm, and two protrusion portions 15 having a height of 0.25 mm are provided on the substrate 2b on an opposite side of the surface on which the piezoelectric element 3b is provided.

Considering the results of Example 1, the thickness of the piezoelectric layer 6b of the piezoelectric element 3b is set to 10 μm, and the thickness of the electrode layers 5b, 7b is set to about 5 μm.

Further, the thickness of the ceramics layer 4b is 7.5 μm. The protrusion portions 15 can be formed on the back surface of the substrate 2b made of alumina by scraping off a portion other than the protrusion portions 15 by blasting.

Two high-frequency voltages having different phases are supplied between the electrode layers 5b-1, 7b-1 and between the electrode layers 5b-2, 7b-2 from the external power source for controlling the vibration of the piezoelectric element 3b.

The piezoelectric active parts of the piezoelectric layer 6b where the two divided electrode layers 5b-1, 7b-1 and the two divided electrode layers 5b-2, 7b-2 are opposed expand or contract due to the high-frequency voltages, and the expansion and contraction are transmitted to the substrate 2b via the ceramics layer 4b, with the result that the vibrator 1b is vibrated as a whole.

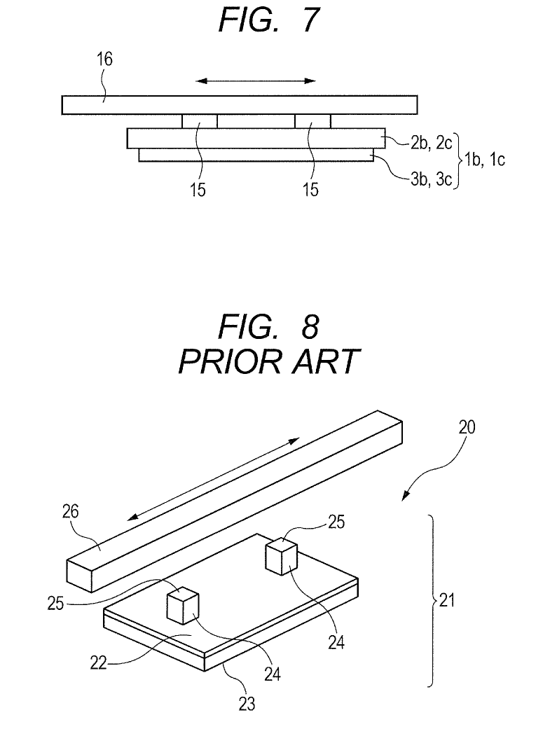

FIG. 7 is a view illustrating a configuration of a linear vibration wave driving device incorporating the vibrator 1b of Example 2 as a driving power source.

The principle of linear driving of the linear vibration wave driving device illustrated in FIG. 7 is the same as that of the conventional example.

A linear slider 16 comes into contact with the protrusion portions 15 in a pressurized state. Then, the vibrator 1b is vibrated due to the vibration of the piezoelectric element 3b to excite elliptic motion in the protrusion portions 15, and the linear slider 16 serving as an object to be driven reciprocates in directions indicated by the arrows due to the elliptic motion. The protrusion portions 15 are made of alumina and have abrasion resistance, similarly to the vibrator 1b.

### Example 3

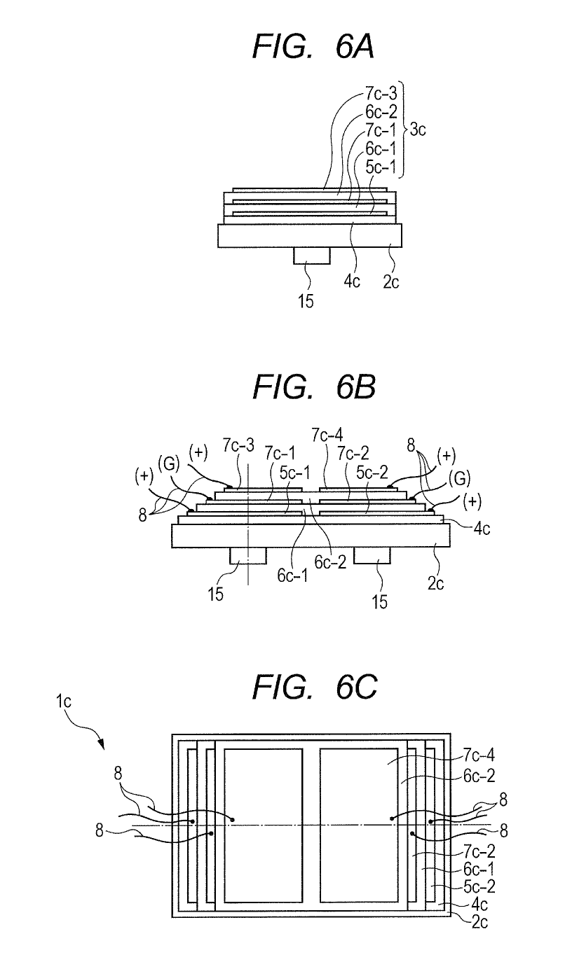

As Example 3, an exemplary configuration of a vibrator in a different form from Examples 1 and 2 is described with reference to FIGS. 6A to 6C. FIGS. 6A, 6B, and 6C are a front view, a side view, and a plan view, respectively.

In a vibrator 1c of this example, as illustrated in FIGS. 6A to 6C, respective layers are successively laminated on a plate-shaped substrate 2c as follows.

That is to say, electrode layers 5c-1, 5c-2, a piezoelectric layer 6c-1, electrode layers 7c-1, 7c-2, a piezoelectric layer 6c-2, and electrode layers 7c-3, 7c-4 are successively laminated as a laminated piezoelectric element 3c on the plate-shaped substrate 2c via a ceramics layer 4c. Then, the two divided electrode layers 5c-1 and 5c-2 are insulated from each other. Similarly, the two divided electrode layers 7c-1 and 7c-2 and the two divided electrode layers 7c-3 and 7c-4 are respectively insulated from each other.

The two divided electrode layers 5c-1, 5c-2 and the two divided electrode layers 7c-1, 7c-2 are respectively opposed to each other with the piezoelectric layer 6c-1 interposed therebetween.

Similarly, the two divided electrode layers 7c-1, 7c-2 and the two divided electrode layers 7c-3, 7c-4 are respectively opposed to each other with the piezoelectric layer 6c-2 interposed therebetween.

Although there is one piezoelectric layer 6b in the vibrator 1b according to Example 2, there are two piezoelectric layers 6c-1, 6c-2 in the vibrator 1c according to Example 3. That is to say, Example 3 is the laminated piezoelectric element which is basically the same as that of Example 2 except that one more piezoelectric layer and one more electrode layer are added further to Example 2.

In Example 3 including two piezoelectric layers, a voltage can be decreased and a high displacement (strain) can be obtained, compared to Example 2 including one piezoelectric layer. A voltage can be further decreased by including three or more piezoelectric layers.

In the vibrator 1c of Example 3, for example, the substrate 2c has a length of 12 mm, a width of 8 mm, and a thickness of 0.25 mm.

Note that, the production method, and the substrate, piezoelectric layer, electrode layer, and ceramics layer used in this example are basically the same as those of Example 1.

Further, for the electrical conduction with an external power source and the polarization treatment, six conductive wires 8 are fixed to surfaces of six electrode layers: two divided electrode layers 5c-1, 5c-2; two divided electrode layers 7c-1, 7c-2; and two divided electrode layers 7c-3, 7c-4 through solder or the like.

After that, basically in the same way as in Example 1, the polarization treatment was performed in a manner that a DC voltage (about 1 V/μm per thickness of the piezoelectric layer 6b) was applied between the electrode layers 5c-1 and 7c-1, between the electrode layers 7c-1 and 7c-3, between the electrode layers 5c-2 and 7c-2, and between the electrode layers 7c-2 and 7c-4 through the conductive wires 8 for about 30 minutes on a hot plate heated to a high temperature of 170° C. to 200° C., with the electrode layers 7c-1, 7c-2 being a ground (G) and the electrode layers 5c-1, 7c-3, 5c-2, and 7c-4 being a plus (+).

Regions of the piezoelectric layers 6c-1 and 6c-2, subjected to the polarization treatment, sandwiched by the electrode layers are layers serving as piezoelectric active parts for generating a displacement, and the piezoelectric characteristics of the layers are directly related to the piezoelectric characteristics of a vibrating plate and to the performance of a vibration wave driving device.

The thickness of the piezoelectric layers 6c-1, 6c-2 of the piezoelectric element 3c is about 20 μm, and the thickness of the electrode layers 5c-1, 5c-2, 7c-1, 7c-2, 7c-3, and 7c-4 is about 5 μm.

Further, the thickness of the ceramics layer 4c is about 15 μm. Two protrusion portions 15 having a height of 0.25 mm are provided on the substrate 2c. The protrusion portions 15 can be formed on the back surface of the substrate 2c made of alumina by scraping off a portion other than the protrusion portions 15 by blasting.

High-frequency voltages having different phases are supplied between the electrode layers 5c-1, 7c-1, 7c-3 and the electrode layers 5c-2, 7c-2, 7c-4 from the external power source for controlling the vibration of the piezoelectric element 3c.

The respective piezoelectric active parts of the piezoelectric layers 6c-1 and 6c-2 where the electrode layers 5c-1, 7c-1, 7c-3 and the electrode layers 5c-2, 7c-2, 7c-4 are opposed expand or contract (are strained), and the expansion and contraction are transmitted to the substrate 2c through the ceramics layer 4c, with the result that the vibrator 1c is vibrated as a whole.

FIG. 7 is a view illustrating a configuration of a linear vibration wave driving device incorporating the vibrator 1c according to Example 3 as a driving power source. The principle of linear driving of the linear vibration wave driving device illustrated in FIG. 7 is the same as that of the conventional example. A linear slider 16 comes into contact with the protrusion portions 15 in a pressurized state. Then, the vibrator 1c is vibrated due to the vibration of the piezoelectric element 3c to excite elliptic motion in the protrusion portions 15, and the linear slider 16 serving as an object to be driven reciprocates in directions indicated by the arrows due to the elliptic motion.

Although the electrical conduction between the electrode layers and the external power source is carried out through use of the conductive wires 8 in Example 3, the electrical conduction between the electrode layers and the external power source may be carried out, for example, through use of a flexible circuit board instead of the conductive wires 8.

According to the screen printing for forming a layer on a substrate, a thinner layer having a more highly accurate thickness can be formed easily, compared to the above-mentioned lamination using green sheets. In addition, according to the screen printing, an application position can be controlled with higher accuracy, and hence mechanical processing is not required after sintering.

Further, a production facility has low cost. As a result, the production cost becomes much lower than that of a conventional piezoelectric element.

Accordingly, the vibrator capable of outputting vibration energy with a small loss and good efficiency, for example, by suppressing damping of vibration involved in miniaturization with a low-cost configuration, the production method for the vibrator, and the vibration wave driving device using the vibrator can be realized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-267650, filed Dec. 6, 2012, which is hereby incorporated by reference herein in its entirety.

What is claimed is:

1. A vibrator, comprising:
a substrate;
a piezoelectric element including a piezoelectric layer and an electrode layer, the piezoelectric element being fixed to the substrate; and
a ceramics layer disposed between the substrate and the piezoelectric element, the ceramics layer having a thickness of more than 0.5 times and less than 1 time a thickness of the piezoelectric layer.

2. A vibrator according to claim 1, wherein the ceramics layer contains an unevenly distributed glass component.

3. A vibrator according to claim 1, wherein the ceramics layer contains a glass component of melted glass powder.

4. A vibrator according to claim 3, wherein the glass component contained in the ceramics layer contains silicon oxide and boron oxide as main components and is added in an amount of 0.5% by weight or more and 10% by weight or less with respect to a weight of ceramics powder of the ceramics layer.

5. A vibrator according to claim 1, wherein the ceramics layer contains as a main component the same component as that of the piezoelectric layer.

6. A vibrator according to claim 1, wherein the piezoelectric layer contains lead zirconate and lead titanate as main components.

7. A vibrator according to claim 1, wherein the substrate comprises alumina having a purity of 99.5% by weight or more and 99.99% by weight or less.

8. A vibrator according to claim 1, wherein the piezoelectric element is fixed to the substrate by baking via the ceramics layer.

9. A vibration wave driving device, comprising as a driving power source the vibrator according to claim 1.

10. A method of producing a vibrator, comprising:
forming a ceramics layer containing glass powder on a substrate;
forming a piezoelectric element including a piezoelectric layer and an electrode layer on the ceramics layer; and
integrating the substrate, the ceramics layer, and the piezoelectric element by baking the substrate, the ceramics layer, and the piezoelectric element together,
wherein as the glass powder containing silicon oxide, boron oxide, and at least one kind of alkali earth metal oxide is used, and
wherein the ceramics layer contains the glass powder in an amount of 0.5% by weight or more and 10% by weight or less with respect to a weight of ceramics powder of the ceramics layer and is formed on the substrate to a thickness of more than 0.5 times and less than 1 time a thickness of the piezoelectric layer.

11. A method of producing a vibrator according to claim 10, wherein the ceramics layer contains the same main component as a main component of the piezoelectric layer.

12. A method of producing a vibrator according to claim 10, wherein the piezoelectric layer contains lead zirconate and lead titanate as main components.

13. A method of producing a vibrator according to claim 10, wherein the substrate comprises alumina having a purity of 99.5% by weight or more and 99.99% by weight or less.
